(19) United States
(12) Patent Application Publication
(10) Pub. No.: US 2022/0029615 A1
(43) Pub. Date: Jan. 27, 2022

(54) CIRCUIT FOR IMPROVING THE SWITCHING SPEED OF A POWER ELECTRONIC SWITCHING CHIP AND APPLICATIONS THEREOF

(71) Applicant: Jianhua LYU, Suzhou City (CN)

(72) Inventors: Jianhua LYU, Suzhou City (CN); Xinghua LYU, Suzhou City (CN)

(21) Appl. No.: 17/478,254

(22) Filed: Sep. 17, 2021

Related U.S. Application Data
(63) Continuation of application No. PCT/CN2019/120821, filed on Nov. 26, 2019.

(30) Foreign Application Priority Data
Mar. 29, 2019 (CN) 201910259042.X

(51) Int. Cl. H03K 17/041; H03K 17/60; H03K 17/74; H02M 1/08; H02M 7/48; H02M 7/5387

(52) U.S. Cl. CPC H03K 17/04113; H03K 17/60; H02M 7/5387; H02M 1/08; H02M 7/4807; H03K 17/74

(57) ABSTRACT

A circuit for improving the switching speed of a power electronic switching chip and application thereof are provided. The design method of improving the switching speed of the power electronic switching chip is to switch its state in the saturated conductive state to the simulated saturated-high-on-voltage state which is much higher than the traditional low-saturated-on-voltage state. In this way, the carrier density in the base region and the trailing time constant are greatly reduced and the total power consumption of trailing in the cut-off period can be greatly reduced, and the design limit of switching speed can be improved and the service reliability can be achieved. Therefrom, a design method for power supply of high frequency power electronic transformer (converter) is further disclosed.

### TECHNICAL FIELD

The invention relates to a circuit for improving the switching speed of a power electronic switching chip and applications thereof, specifically refers to a method for improving the switching speed of power electronic switching chips and the application thereof in high frequency power electronic transformer (converter) with reactive power capacity to meet the power supply function requirements of variable loads.

### BACKGROUND

The development of device manufacturing in the electronic industry can be divided into two categories from the perspective of use. One is the relatively traditional and mature weak electricity industry, widely used and also in the rapid development, and the other is the power electronic power components used in the strong electricity industry. The development of power electronic power components can be roughly divided into several stages, such as ordinary transistor, thyristor, large transistor composite module GTR and IGBT. One of the performance characteristics symbolizing the development degree of this kind of power electronic power components is that their switching speed is gradually improved with the emergence of new devices. Because of the classical upper limit of switching speed of all kinds of devices, the acceleration of this kind of power electronic power components has become the application bottleneck of switching components and has become the development frontier. Because the higher the carrier density in the base area when the switching component is on, the greater the trailing current generated when the switching component is off. When the components are turned off each time, the power consumption in the tailing time constant to segment can reach the order of magnitude of the output power and far exceed the rated power consumption of the switching components, even if the switching cycle is only shortened a little, it may lead to the increase of the total average power consumption of the switching components greatly exceeds the limit that the components can bear and can not work normally. For the same working current, the switching speed of power electronic power components can be greatly improved by greatly reducing the carrier density in the base area, for this, people have thought a lot of ways and tried a lot of technical measures, but there has been no major breakthrough.

Because of the high turn-off power, people can only extend the switching cycle to limit the average power consumption of the components, and the switching cycle of the switching components has a special variable value and has to be limited, not to be too short. Therefore, when such components are used, the setting of their switching frequency cannot too high and must be determined by the upper limit of the switching frequency corresponding to the type of switching components used. In addition, even if the switching speed of the component is limited, the power consumption impact of the trailing time constant to segment still exceeds the limit that the component can bear when the component is shut down each time, which implicitly reduces the reliability and normal life of the component.

In the contemporary era of high development of electronic technology, electronic transformers quickly replaced many traditional heavy power frequency transformers because ifs small, efficient and has low cost and other huge technical advantages. However, there are still a considerable number of power frequency power transformers have not been able to obtain such a replacement. The reason for this is that for many applications, the need for a power supply with drastically varying loads can cause problems with reactive power reserve capacity requirements. Because the phase is involved, the simple electronic transformer designed at present cannot meet some general requirements of reactive power operation.

The development of power electronic switching device components capable of withstanding UHV can easily simplify the design to develop and produce power electronic transformers in the UHV range to meet all requirements. To improve the withstand voltage of power electronic switching devices, a large number of conventional power electronic switching device units with low capability of withstand voltage can be combined in series into a switching device assembly with extremely high capability of withstand voltage to solve the technical bottleneck of UHV power electronics transformer design, to meet the extensive and urgent technical needs. However, the problem of voltage-sharing between the units in series can not be solved in a series.

Now, low voltage power supply is adopted for a wide variety of small household appliances, and there is a considerable demand for low voltage power electronic transformer power supply. There are a large number of common inverter, frequency conversion power supply, electric welding machine, induction cooker, microwave oven, induction heating furnace and other equipment applied in UHV transmission, etc. even the wireless power transmission project (in fact, induction cooker and maglev train are all examples of the application of wireless power transmission), such as for electric vehicles that do not carry on board power batteries (public transportation is a good starting platform for this new technology), high-speed rail that transmit wirelessly, especially suitable to provide power at high frequencies, these all need power electronics transformers. In the design of electronic transformer (converter) power supply of this kind of products, because of the limitations of the current technical level, the circuit design has to be very complicated, which brings about problems of the efficiency, reliability and even feasibility.

With the deterioration of the earth's environment in recent years, catastrophic weather extremes have cropped up from time to time. The freezing weather we have experienced in the 2008 Spring Festival transportation, which has a great impact on the transmission line. When the line is set up, the cost of strengthening and maintaining the lines is far greater than the loss caused by such rare disasters. The most desirable method is to apply the high frequency current on-line heating transmission line with high frequency skin effect and easy frequency division power supply operation to carry out on-line anti icing and ice melting treatment, however, due to the limitations of the current power supply design (only power electronic transformer is required) that can meet this need, this assumption in the industry still remains in imagination.

Modem medical statistics indicate that more than 10 percent of the population has a variety of sensory or unconscious stones in their bodies, in serious cases, the stones can lead to more serious diseases, such as uremia, kidney necrosis, or even life-threatening deterioration. It has caused great suffering to patients and their families, and caused serious damage to properly and families. It's also a huge drain on the nation's health resources. The traditional treatment of stones in the human body requires medication or surgery, but it is easy to relapse after surgery, not easy to break the root from the existing curative effect. Some people also produce a kind of equipment that can remove some minerals in water, such as calcium ions, to reduce the possibility of stones. But such an approach is undesirable. Because substances such as calcium are essential to the body, the lack of which can lead to other diseases. It has been proved that the electro-magnetization treatment of drinking water can effectively prevent and eliminate stones in the human body to a considerable extent, so as to achieve the purpose of auxiliary health care against stones, thereby reducing the incidence of stones in the body, improving the deterioration of stone disease, and smoothing the circulation system in the human body, especially the microcirculation system, in this way, this can be developed according to the principle of “If qi and blood are smooth, there will be no pain. If there is pain, it means qi and blood are blocked” of traditional Chinese medicine. The water source is treated by electro-magnetization to activate the water to obtain the special physiotherapy and health care function of “if qi and blood are smooth, there will be no pain”. Because the application of high frequency electronic transformer power supply does not consume much active power but only requires high intensity of high frequency electromagnetic field to obtain the effect of the degree of electromagnetic treatment of water, the power supply needs to provide strong reactive power.

### SUMMARY OF THE INVENTION

The object of the invention is to provide a principle of “greatly increasing the on voltage of the electronic switch can greatly reduce the trailing carrier density of the switch chip” based on the simple logical causality of Newton's law and Ohm's law, which overturns the traditional design and implementation of the concept of “saturation state voltage” taken as low as possible when conducting the current technology, wherein a value is taken as the conduction range of an electronic switch, much higher than the conventional value, usually not imagined and never used. In this way, the traditional problem of reducing the carrier density in the on-conducting state is solved. The time constant to of the trailing current in the base area of bipolar power transistor is greatly shortened, the switching speed is greatly improved and the damage caused by trailing current to devices is reduced to improve the reliability of the design method of power electronic switching chips.

The invention also discloses the application of high-speed power electronic switching module to replace the traditionally used power electronic switching device or the module directly combining the energy storage resonant LC circuit to form a power electronic transformer, wherein it can accommodate the normal existence and operation of high-frequency reactive power to cope with the needs of different loads, and achieve a design method which can completely replace the heavy frequency transformer. And the UHV power electronic switching device assembly designed based on the power electronic switching device or module in series voltage balancing is simple to form the power electronic transformer which can be applied to above power electronic transformer on UHV occasions.

To realize the above objects, the invention provides a technical scheme as follows: a circuit for improving the switching speed of a power electronic switching chip, which comprises a power electronic switching chip and a simulated saturation conduction high voltage function setting circuit, wherein the simulated saturation conduction high voltage function setting circuit is connected with the power electronic switching chip to form a high-speed power electronic switching module; the simulated saturation conduction high voltage function setting circuit greatly increases the voltage of the “saturation” conduction of the power electronic switching chip and correspondingly greatly reduces the carrier density in the base region of the power transistor of the power electronic switching chip, thereby improving the switching speed of power electronic switching chip;

The simulated saturation conduction high voltage function setting circuit includes NPN power transistor 2 for power electronic switching chips, simulated saturation voltage setting voltage unit 4, clamping diode 5, load resistor R_{f} 9, drive pulse current limiting resistor Rᵢ 10, supply voltage 11, drive pulse input terminal 12, drive pulse output end 13, simulated saturation voltage clamp terminal 14;

The anode of the simulated saturation voltage setting voltage unit 4 is connected to the base of the NPN type power transistor 2, which is drive pulse output end 13. The cathode of the simulated saturation voltage setting voltage unit 4 is connected with the anode of the clamping diode 5 and the driving pulse input terminal 12. The cathode of the clamping diode 5 is connected to the collector of NPN type power transistor 2 via simulated saturation voltage clamping terminal 14. The conduction pulse is input to the drive pulse input terminal 12 through the current limiting resistor 10 via the pulse input terminal 8. The drive pulse input terminal is connected to the base of the NPN type power transistor 2 via the simulated saturation voltage setting voltage unit 4. In this way, the NPN power transistor 2 of the power electronic switching chip is conduced in the simulated saturation state of high conduction voltage.

A power electronics transformer circuit with a fast switching high frequency reactive power oscillating circuit, wherein the power electronics transformer circuit adopts the high-speed power electronic switching module according to claim 1, wherein the module and LC circuit are connected alone or as a bridge arm in series or in parallel to form a “single tube”, half bridge or full bridge LC self excitation or separate excitation oscillation circuit and to form a energy storage resonant circuit together with inductive or capacitive load elements, and with the filter capacitance push-pull complement to get 360° full period rectifier circuit.

As an improvement, power electronic transformer circuit comprises an self-excited power electronics transformer circuit with a high frequency reactive power capacity composed of a single high speed power electronics switch module and the LC circuit, and the self-excited parallel full bridge power electronic transformer circuit with high frequency reactive power capacity composed of a plurality of high speed power electronic switching modules and the LC circuit, a self-excited parallel half bridge power electronic transformer circuit with high frequency reactive power capacity, a self-excited series full bridge power electronic transformer circuit with high frequency reactive power capacity, and a self-excited series half bridge power electronic transformer circuit with high frequency reactive power capacity.

As an improvement, the self-excited power electronics transformer circuit with high frequency reactive power capacity comprises a high speed power electronic switching module 20 with a simulated saturation high conduction voltage, reactive power capacitance 23 in the LC circuit, the transformer and converter output primary winding 24 as the main inductance of the reactive power LC circuit, the tap 24c of the primary winding 24, the secondary winding 25 of the transformer and converter output, inductance 22, capacitor 122, current limiting resistor 27, capacitor 28, transformer converter 32, power positive terminal 30, the reactive power LC main circuit is formed in parallel by the capacitance 23 and the primary winding 24 of the transformer and converter output.

One end of the LC main circuit is connected to the D pole of the high-speed power electronic switching module 20, the other end is connected to the end of capacitance 28, the other end of capacitance 28 is connected to the current limiting resistor 27, the other end of the current limiting resistor 27 is connected to the G pole of the high-speed power electronic switching module 20, one end of the inductance 22 is connected to one end of the capacitance 122 and is connected to the tap 24c of the primary winding 24 of the transformer and converter output, the other end of the inductance 22 is connected to the power positive terminal 30, the other end of capacitance 122 is grounded, the S pole of high speed power electronic switching module 20 is grounded.

As an improvement, the self-excited parallel full bridge power electronic transformer circuit with high frequency reactive power capacity comprises 20a, 20b, 21a, 2.1b four high-speed power electronic switching modules with simulated saturation and high conduction acceleration, reactive power hedge inductance 22, reactive power LC circuit capacitance 23, the transformer and converter output primary winding 24 as the main inductance of the reactive power LC circuit, the secondary winding 25 of the transformer and converter output, the current limiting resistance 26a, 26b, 27a, 27b, the capacitance 28a, 28b, 29a, 29h, the power positive terminal 30, the transformer and converter output end 31, the transformer converter 32, the self excited feedback winding 50a, Sob, 51a, 51b.

One end of the inductance 22 is connected to the power positive terminal 30, the other end is connected to the D pole of the high-speed power electronic switching module 20a, 21a, the S pole of the high-speed power electronic switching module 21a is connected to the D pole of the high-speed power electronic switching module 20b, the S pole of the high-speed power electronic switching module 20a is connected to the D pole of the high-speed power electronic switching module 21b, the S pole of the high-speed power electronic switching module 20b, 21b is grounded, the end of the self excited feedback winding 50a is connected to the S pole of the high-speed power electronic switching module 21a, the other end is connected to the capacitance 28a, the other end of the capacitance 28a is connected to the resistance 26a, the other end of the resistance 26a is connected to the G pole of the high-speed power electronic switching module 21a, the end of the self excited feedback winding 50b is connected to the S pole of the high-speed power electronic switching module 21b, the other end is connected to the capacitance 28b, the other end of the capacitance 28b is connected to the resistance 26b, the other end of the resistance 26b is connected to the G pole of the high-speed power electronic switching module 21b, the end of the self excited feedback winding 51a is connected to the S pole of the high-speed power electronic switching module 20a, the other end is connected to the capacitance 29a, the other end of the capacitance 29a is connected to the resistance 27a, the other end of the resistance 27a is connected to the G pole of the high-speed power electronic switching module 20a, the end of the self excited feedback winding 51b is connected to the S pole of the high-speed power electronic switching module 20b, the other end is connected to the capacitance 29b, the other end of the capacitance 29b is connected to the resistance 27b, the other end of the resistance 27b is connected to the G pole of the high-speed power electronic switching module 20b, the end of the capacitance 23 is connected to the end of the primary winding 24 of the transformer and converter output, and then connected to the S pole of the high-speed power electronic switching nodule 20a, the other end of the capacitance 23 is connected to the other end of the primary winding 24 of the transformer and converter output, and then connected to the S pole of the high-speed power electronic switching module 21a.

As an improvement, the self-excited parallel half bridge power electronic transformer circuit with high frequency reactive power capacity comprises 20, 21 two high-speed power electronic switching modules with simulated saturation and high conduction acceleration, inductance 22, capacitance 23, the transformer and converter output primary winding 24 as the main inductance of the reactive power LC circuit, the centre tap 24M of the primary winding 24, the secondary winding 25 of the transformer and converter output, the current limiting resistance 26, 27, the capacitance 28, 29, the power positive terminal 30, the transformer converter 32.

The end of the inductance 22 is connected to the power positive terminal 30, the other end is connected to the centre tap 24M of the primary winding 24 of the transformer and converter output, the D pole of the high-speed power electronic switching module 20 is connected to the end of the primary winding 24 of the transformer and converter output, the D pole of the high-speed power electronic switching module 21 is connected to the other end of the primary winding 24 of the transformer and converter output, both of the two S poles of the high-speed power electronic switching modules are grounded, the end of the capacitance 23 is connected to the D pole of the high-speed power electronic switching module 20, the other end is connected to the D pole of the high-speed power electronic switching module 21, the D pole of the high-speed power electronic switching module 20 is connected to the end of capacitance 28, the other end of capacitance 28 is connected to the end of resistance 26, the other end of resistance 26 is connected to the G pole of the high-speed power electronic switching module 21, the D pole of the high-speed power electronic switching module 21 is connected to the end of capacitance 29, the other end of capacitance 29 is connected to the end of resistance 27, the other end of resistance 27 is connected to the G pole of the high-speed power electronic switching module 20.

As an improvement, the self-excited series full bridge power electronic transformer circuit with high frequency reactive power capacity comprises 20a, 20b, 21a, 21b four high-speed power electronic switching modules with simulated saturation and high conduction acceleration, capacitance 23, the transformer and converter output primary winding 24 as the main inductance of the reactive power LC circuit, the secondary winding 25 of the transformer and converter output, the current limiting resistance 26a, 26b, 27a, 27b, the resistance 54. the capacitance 55, the resistance 56, the bidirectional diode 57, the power positive terminal 30. the transformer and converter output end 31, the transformer converter 32, the self excited feedback winding 50a, 50b, 51a, 51b, 52, the feedback winding combination 53, the overvoltage diode 58a, 58b, 59a, 59b.

The power positive terminal 30 is connected to the D pole of the high-speed power electronic switching module 20a, 21a, the S pole of the high-speed power electronic switching module 20b, 21b is grounded, the S pole of the high-speed power electronic switching module 21a is connected to the D pole of the high-speed power electronic switching module 20b, the S pole of the high-speed power electronic switching module 20a is connected to the D pole of the high-speed power electronic switching module 21b, the end of the capacitance 23 is connected to the end of the primary winding 24 of the transformer and converter output, the other end of the capacitance 23 is connected to the S pole of the high-speed power electronic switching module 20a, the other end of the primary winding 24 of the transformer and converter output is connected to the end of self excited feedback winding 52, the other end of self excited feedback winding 52 is connected to the S pole of the high-speed power electronic switching module 21a, the end of self excited feedback winding 50a is connected to the S pole of the high-speed power electronic switching module 21a, the other end is connected to the resistance 26a, the other end of the resistance 26a is connected to the G pole of the high-speed power electronic switching module 21a, the end of self excited feedback winding 51a is connected to the S pole of the high-speed power electronic switching module 20a, the other end of the resistance 27a, the other end of the resistance 27a is connected to the G pole of the high-speed power electronic switching module 20a, the end of self excited feedback winding 51b is connected to the S pole of the high-speed power electronic switching module 20b, the other end is connected to the resistance 27b, the other end of the resistance 27b is connected to the G pole of the high-speed power electronic switching module 20b, the end of self excited feedback winding 50b is connected to the S pole of the high-speed power electronic switching module 21b, the other end is connected to the resistance 26b, the other end of the resistance 26b is connected to the G pole of the high-speed power electronic switching module 21b, the end of the resistance 54 is connected to the power positive terminal 30, the other end is connected to the capacitance 55 and the resistance 56, the other end of the resistance 56 is connected to the bidirectional diode 57, the other end of the capacitance 55 is grounded, the other end of the bidirectional diode 57 is connected to the G pole of the high-speed power electronic switching module 21b, the anode of the diode 58a is connected to the S pole of the high-speed power electronic switching module 21a, the cathode is connected to the D pole of the high-speed power electronic switching module 21a, the anode of the diode 59a is connected to the S pole of the high-speed power electronic switching module 20a, the cathode is connected to the D pole of the high-speed power electronic switching module 20a, the anode of the diode 58b is connected to the S pole of the high-speed power electronic switching module 21b, the cathode is connected to the D pole of the high-speed power electronic switching module 21b, the anode of the diode 59b is connected to the S pole of the high-speed power electronic switching module 20b, the cathode is connected to the D pole of the high-speed power electronic switching module 20b.

As an improvement, the self-excited series half bridge power electronic transformer circuit with high frequency reactive power capacity comprises 20, 21 two high-speed power electronic switching modules with simulated saturation and high conduction acceleration, capacitance 23, the transformer and converter output primary winding 24 as the main inductance of the reactive power LC circuit, the secondary winding 25 of the transformer and converter output, the secondary winding output 31, the self excited feedback winding 50, 51, the diode 58, 59, the load winding 60, the increasing reactive power capacitance 61, the current limiting resistance 26, 27, the capacitance 28, 29, the power positive terminal 30, the transformer converter 32.

The D pole of the high-speed power electronic switching module 21 is connected to the power positive terminal 30, the S pole of the high-speed power electronic switching module 21 is connected to the end of the primary winding 24 of the transformer and converter output and the D pole of the high-speed power electronic switching module 20, the other end of the primary winding 24 of the transformer and converter output is connected to the capacitance 23, the other end of the capacitance is grounded, the S pole of the high-speed power electronic switching module 20, the end of the secondary winding 25 is connected to the capacitance 61, the other end of the capacitance 61 and the other end of the secondary winding 25 are connected to the load winding 60 as the output end 31, the end of the self excited feedback winding 50 is connected to the S end of the high-speed power electronic switch module 21, the other end is connected to the capacitance 28, the other end of the capacitance 28 is connected to the end of the resistance 26, the other end of the resistance 26 is connected to the G pole of the high-speed power electronic switching module 21, the end of the self excited feedback winding 51 is connected to the S end of the high-speed power electronic switch module 20, the other end is connected to the end of the capacitance 29, the other end of the capacitance 29 is connected to the end of the resistance 27, the other end of the resistance 27 is connected to the G pole of the high-speed power electronic switching module 20, the anode of diode 58 is connected to the S pole of the high-speed power electronic switching module 21, the cathode is connected to the D pole of the high-speed power electronic switching module 21, the anode of diode 59 is connected to the S pole of the high-speed power electronic switching module 20, the cathode is connected to the D pole of the high-speed power electronic switching module 20.

An UHV power electronics transformer circuit composed of an UHV power electronic switching device assembly, which comprises that the component assembly of a high-speed power electronic switching module capable of withstanding UHV is matched alone or as a bridge arm with UHV LC circuit in series or in parallel with the single arm, half bridge or full bridge to form the LC oscillating circuit, and forms an UHV energy storage resonance circuit together with inductive or capacitive load elements, and with the filter capacitance push-pull complement 360° all conduction half bridge rectifier;

The component assembly of a power electronic switching module capable of withstanding wherein its technical feature is hereinafter, in particular, in addition to several to hundreds or even more N sets with three conventional I/O ports defined according to D, S, G, they are also equipped with a group of lower withstand voltage power electronic device combination units, wherein the maximum trailing voltage range is M control inputs terminals corresponding to M voltage intervals at the subdivision turn-off, and then to form the component assembly of a UHV power electronic switch in series. The component assembly of a power electronic switch is the feedback output of real-time trailing voltage boost obtained by using optocoupler optical fiber to differentiate N lower withstand voltage power electronic switching device combination units in series according to M interval voltages in the process of cut-off trailing voltage boost, and then send to M and gate entrances respectively with the same grade interval voltage, each and gate output is then transmitted to the control input terminals of the upper interval voltage of each lower withstand voltage power electronic switching device combination unit by optocoupler optical fiber, when N lower withstand voltage power electronic switching device combination units are shut off, the trailing voltage in the rising process reaches the top of the same original interval voltage before entering the upper interval voltage together. The actual interval voltage borne by all N lower withstand voltage power electronic switching device combination units always keeps the same interval voltage synchronization when the tail voltage of the whole assembly is in the boost process of turning off the tail and safely increases synchronously with the interval voltage conversion in the tail stage. Until the trailing current disappears, it can form the component assembly of a simple and reliable UHV buck-boost conversion power electronic switching device or module, and form a single-arm or full-bridge or half-bridge energy storage resonant circuit with UHV LC circuit in series or in parallel, and form an UHV power electronic transformer with high frequency reactive power capacity;

The component assembly of the high-speed power electronic switching module that can withstand UHV includes N identical power electronic switch device combination units, UHV power positive terminal 30, load 114, and gate 115, N main switch pulser 102j synchronous controller 117; the power electronic switching device combination unit is composed of the high-speed power electronic switching module in claim 1 as the basic unit.

As an improvement, each individual power electronic switching device combination unit j is independently distinguished from other power electronic switching device combination units, and is connected to other power electronic switching device combination units by series positive port 112j and series negative port 113j which are connected in series with other units. The series positive port 112j of each power electronic switching device combination unit is connected to the negative port 113j+1 of the last power electronic switching device combination unit. The serial positive port 112N of the highest power electronic switching device assembly unit is connected to the end of load 114 as the D end of the component assembly of the UHV power electronic switch, the other end of load 114 is connected to UHV power positive terminal 30, The negative port 1131 of the lowest power electronic switching device combination unit is used as the S end of the component assembly of the UHV power electronic switch. There are M sets of optocoupler light emitting diodes 105jk optocoupler optical fiber 109jk of optocoupler light derived from each k-level voltage interval. The N roots of each k-level voltage interval group are respectively connected to the N entrances of each M K-level and gate 115K. K-level and gate 115K output N outlets through the optocoupler optical fiber 110jk send the k-level synchronous optocoupler light output by the voltage in the last interval to the k-level receiving end of the power electronic switching device combination unit 101j, and control the power electronic switching device combination unit 101j from the voltage state of the k-level interval to the voltage state of the next k±1 interval synchronously and uniformly. The input terminal of controller 117 is used as the control end G of the oscillating excitation switch of the component assembly of a UHV power electronic switch.

As an improvement, the circuit of the single self-equalizing power electronic switching device combination unit j (j=1˜N, similarly hereinafter) is connected in series by the component assembly of a power electronic switching module, which comprises power electronic switching devices 101j, main switch drives pulser 102j, diode 103j, capacitor 104j, M optocoupler light emitting diodes 105jk(k=1˜M, similarly hereinafter), M diodes 106jk, M partial voltage resistance 107jk, M current limiting resistors 108jk, M export optocoupler light emitting diodes 105jk optocoupler optical fiber 109jk of optocoupler light, M receiver optocoupler optical fiber 110jk, optocoupler optical fiber 111j synchronized with main switch drive pulser 102j, the series positive port 112j and the series negative port 113j which is connected in series with other units, buck sampling resistance 119j, 120j, reference zener diode and current limiting resistance 118j thereof.

The D end of the power electronic switching device 101j is connected to the series positive port 112j, the S end of the power electronic switching device 101j is connected to the series negative port 113j, the G end and Ga end of the power electronic switching device 101j are connected to the control pulse output end of the main switch drive pulser 102j, the anode of diode 103j is connected to a series positive port 114 the cathode is connected to one end of the capacitor of 104j, the other end of capacitor 104j is connected to the series negative port 113j, the power positive terminal of the main switch drive pulser 102j is connected to the cathode of the diode 103j, the power negative terminal of the main switch drive pulser 102j is connected to the series negative port 113j, M resistors 107jk in series, the upper end of the partial resistance 107jk is connected with the lower end of the partial resistance 107jk+1, and then the upper end of the resistance 107jM is connected to the cathode of the reference zener diode 121j and connected with one end of the current limiting resistance 118j, the other end of the current limiting resistor 118j is connected to the cathode of the diode 103j, the anode of the reference zener diode 121j is connected to the series negative port 113j, the lower end of the resistance 107j1 is connected to the series negative port 113j, the end of the buck sampling resistance 120j is connected to the series negative port 113j, the upper end of the buck sampling resistance 119j is connected to the series positive port 112j, the lower end is connected to the other end of the buck sampling resistance 120j and connected to the cathode of all the optocoupler light emitting diodes 105jk, the anode of each optocoupler light emitting diodes 105jk is connected to the cathode of 106jk, the anode of each diode 106jk is connected to the end of each resistor 108jk, the other end of each resistance 108jk is respectively connected to the connection point of the partial voltage resistance 107jk and 107jk+1;

As an improvement, the circuit of UHV power electronics transformer comprises the circuit of an UHV power electronics transformer consisting of a single assembly of UHV power electronics switching devices, a parallel full bridge UHV power electronic transformer circuit and a parallel half bridge UHV power electronic transformer circuit composed of multiple UHV power electronic switching device assemblies.

As an improvement, the circuit of the UHV power electronic transformer comprises a single UHV power electronic switching device assembly 20, capacitance 23 of reactive power LC circuit, the transformer and converter output primary winding 24 as the main inductance of the reactive power LC circuit, the secondary winding 25 of the transformer and converter output, inductance 22, capacitance 122, transformer converter 32, power positive terminal 30

The capacitance 23 is connected with the primary winding 24 of the transformer and converter output to form the reactive power LC main circuit, the end of the LC main circuit is connected to D pole of the UHV power electronic switching device assembly 20, the other end of the LC main circuit is connected with the end of the inductance 22 and the end of the capacitance 122, the other end of the inductance 22 is connected to the UHV power positive terminal 30, the other end of capacitance 122 is grounded, the S pole of the UHV power electronic switching device assembly 20 is grounded, the G pole of the UHV power electronic switching device assembly serves as the control input of the oscillating excitation switch;

As an improvement, the parallel full bridge UHV power electronic transformer circuit comprises 20a, 20b, 21a, 21b four UHV power electronic switching device assemblies, reactive power hedge inductance 22, reactive power LC circuit capacitance 23, the transformer and converter output primary winding 24 as the main inductance of the reactive power LC circuit, the secondary winding 25 of the transformer and converter output, power positive terminal 30, transformer converter output 31, transformer converter 32;

The end of the reactive power hedge inductance 22 is connected to the power positive terminal 30, the other end is connected to the D pole of the UHV power electronic switching device assembly 20a and 21a, the S pole of the UHV power electronic switching device assembly 21a is connected to the D pole of the UI-t power electronic switching device assembly 20b. The S pole of the UHV power electronic switching device assembly 20a is connected to the D pole of the UHV power electronic switching device assembly 21b. The S pole of the UHV power electronic switching device assembly 20b and 21b is grounded. The G pole of the UHV power electronic switching device assembly 21a, the G pole of the UHV power electronic switching device assembly 20a, the G pole of the UHV power electronic switching device assembly 21b, and the G pole of the UHV power electronic switching device assembly 20b are used as the control input of the oscillation excitation switch. The end of the capacitance 23 is connected to the end of the inductance 24 and then connected to the S pole of the UHV power electronic switching device assembly 20a, the other end of the capacitance 23 is connected to the other end of the inductance 24, and then connected to the S-pole of the UHV power electronic switching device assembly 21a.

As an improvement, the parallel half bridge UHV power electronic transformer circuit comprises 20, 21 two UHV power electronic switching device assemblies, reactive power hedge inductance 22, capacitance 23, the transformer and converter output primary winding 24 as the main inductance the center tap 24M of the primary winding 24, the secondary winding 25 of the transformer and converter output, power positive terminal 30, transformer converter 32;

The end of the reactive power hedge inductance 22 is connected to the power positive terminal 30, the other end is connected to the center tap 24M of the primary winding 24, the D pole of the UHV power electronic switching device assembly 20 is connected to the end of the primary winding 24, the D pole of the UHV power electronic switching device assembly 21 is connected to the other end of the primary winding 24. The S ends of the two UHV power electronic switching device assemblies are grounded. The end of the capacitor 23 is connected to the D pole of the UHV power electronic switching device assembly 20, and the other end is connected to the D pole of the UHV power electronic switching device assembly 21. The G pole of the UHV power electronic switching device assembly 21 and the G pole of the UHV power electronic switching device assembly 20 serve as the control input of the oscillating excitation switch.

The advantages of the invention over prior art are as follows:

The invention greatly improves the switching speed of the switching element, greatly reduces the power consumption of switching devices and improves the reliability of use thereof.
The electronic switch with increased switching speed is applied to the power electronic transformer circuit of oscillation circuit of high frequency reactive power, wherein it solves the problem that the current simple electronic transformer cannot meet the requirement of reactive power operation.

The electronic switch with increased switching speed is applied to the circuit of UHV power electronics transformer, which can easily simplify the design to develop and produce the power electronics transformer in the UHV range to meet the needs of all aspects.

### BRIEF DESCRIPTION OF THE DRAWINGS

FIG. 1 is the circuit schematic diagram of an independent auxiliary module for setting a simulated saturated simulated saturation high on voltage.

FIG. 2 is the schematic diagram of the circuit of the thyristor high-speed power electronic switching module with high simulated saturation on-voltage speed increase and low turn-off power consumption, super high current and super high voltage endurance.

FIG. 3 is the schematic diagram of the circuit of low turn-off power GTR high speed power electronic switching module with high simulated saturation on-voltage speed increase (or composed of the disaggregated element).

FIG. 4 is the schematic diagram of the circuit of low turn-off power IGBT high speed power electronic switching module with high simulated saturation on-voltage speed increase.

FIG. 5 is the schematic diagram of power electronics transformer circuit with high frequency reactive power oscillating circuit combined by a single high speed power electronics switch module and LC circuit.

FIG. 6 is the schematic diagram of power electronics transformer circuit of parallel full bridge with high frequency reactive power oscillation circuit combined by high speed power electronics switch module and LC circuit.

FIG. 7 is the schematic diagram of power electronics transformer circuit of parallel half bridge with high frequency reactive power oscillation circuit combined by high speed power electronics switch module and LC circuit.

FIG. 8 is the schematic diagram of power electronics transformer circuit of series full bridge with high frequency reactive power oscillation circuit combined by high speed power electronics switch module and LC circuit.

FIG. 9 is the schematic diagram of power electronics transformer circuit of series half bridge with high frequency reactive power oscillation circuit combined by high speed power electronics switch module and LC circuit.

It is also the schematic diagram of the power supply circuit of the health care physiotherapy dredging device which is provided by the power electronic transformer with high frequency reactive power.

FIG. 10 is the circuit diagram of a half-bridge rectifier unit used for converting AC power supply to DC power distribution in a transmission line with DC up and down voltage of power electronics transformers with high frequency reactive power by push-pull complementary filter capacitance to meet 360° full conduction requirements to avoid power factor problems.

FIG, 11 is the schematic diagram of power electronic transformer power supply circuit with half bridge high frequency reactive power for simple anti icing and ice melting setting of transmission line.

FIG. 12 is the section diagram of transmission line with coaxial cable structure for simple anti icing and ice melting.

FIG. 13 is the schematic diagram of power supply circuit of simple anti icing and ice melting coaxial cable structure transmission line erection and connect high frequency power electronic transformer power supply circuit.

FIG. 14 is the layout plan of the complex connected structure wire slot of the large diameter water pipe with the winding of the electromagnetic treatment water coil of the municipal water company.

FIG. 15 is the assembly diagram of complex connected structure wire slot and wound winding in water pipe.

FIG. 16 is a diagram showing the coil winding separately in a water pipe,

FIG, 17 is the schematic diagram of the circuit of an UHV power electronic transformer composed of a single UHV power electronic switching device assembly.

FIG. 18. is the schematic diagram of the circuit of a parallel half bridge UHV power electronic transformer composed of UHV power electronic switching device assembly.

FIG. 19 is the schematic diagram of the circuit of a parallel full bridge UHV power electronic transformer composed of UHV power electronic switching device assembly.

FIG. 20 is the schematic diagram of a unit circuit structure in the UHV switching device assembly.

FIG. 21 is the schematic diagram of the total circuit of the UHV switch component assembly composed of N units in series.

### DESCRIPTION OF EMBODIMENTS

A circuit for improving the switching speed of a power electronic switching chip and its application of the invention will be clearly and completely described hereinafter with reference to the drawings of the invention.

The working principle of the invention:

The invention improves the simulated saturation conduction voltage of power electronic switching chips to get the great reduction of the base of the tail carrier density to replace the traditional use of power electronic switching device or module circuit structure: the drive pulse input of power electronic switching chips adopts series insert fitting saturated conduction voltage setting unit as well as the clamping diode of the collector simulated saturation voltage to increase the traditional low saturation conduction voltage manyfold when the power electronic switching chip is on, adjust the specific value of the setting voltage to set several simulated saturation voltage U-quasi according to the requirements of different circuits, and then set the setting voltage value of the simulated saturation setting voltage unit to get the ideal switching speed. This part of the circuit to improve the simulated saturation conduction voltage of the power electronic switching chip can be combined on the power electronic switching chip of the power module as a component of the module chip, or can be independently designed as a single component as a matching module of the circuit.

The high speed power electronic switching devices or modules with the high conduction are applied to the design of power electronic transformers. The technical feature of the design method is that the high-speed power electronic switching device or module with high conduction voltage acceleration and L, C element are connected alone or as a bridge arm to form the half bridge or full bridge separate excitation or self-excited LC oscillator circuit and inductive or capacitive load elements together to form a general-purpose power electronics transformer with standby high frequency reactive power capacity performance ready to he called at any time to meet the needs of the load on its output changes. Because the increased reactive power exists in L and C oscillating circuits and does not consume electric energy, there is not much additional impact on the power electronics transformer power consumption.

The high speed power electronic switching devices or modules with high conduction acceleration are formed into UHV power electronic switching device assembly in series as the base component unit, which constitutes the power electronic transformer applied to UHV range to meet the requirements of different occasions.

In the design of voltage conversion equipment for UHV DC transmission lines, this kind of high frequency power electronic transformer with reactive power capacity can also be easily applied to simple buck-boost equipment to meet the needs of drastic changes of the power line load.

In order to solve the problem that the high-frequency power electronic transformer applied to the UHV DC transmission line lacks UHV switching devices, the part of the technical solution adopted in the invention is to use several to hundreds or even more N sets with three conventional I/O ports defined according to D, S, G in series in the UHV range, they are also equipped with a group of lower withstand voltage power electronic device combination units, wherein the maximum trailing voltage range is M control inputs terminals corresponding to M voltage intervals at the subdivision turn-off, and then to form the component assembly of a UHV power electronic switch, alone or as a bridge arm with LC circuit in series or in parallel to form “single tube”, half bridge or full bridge LC oscillating circuit, and with inductive or capacitive load elements together to forms a buck-boost power electronic transformer (converter) with high frequency reactive power of the energy storage resonance circuit. The specific method of design the UHV switch component assembly with the unit of the lower voltage resistant module is to make the circuit in series of each unit of the lower voltage resistant power electronic switch component combination module keep the voltage of each interval in the boost process synchronized and self-equalizing voltage when the tail boost is turned off. Thus, the power consumption can be limited to obtain the UHV switch component assembly with a high total voltage withstand when the tail boost is turned off, which can directly form a simple, inexpensive and reliable the high frequency LEV buck-boost conversion power electronics transformers, and directly applied to the buck-boost inverter of all levels of DC voltage without limiting the transmission period, so as to meet the requirements of the power supply function generated by the load that changes normally and dynamically in the normal operation.

The specific self-equalizing voltage technology scheme is that in the process of cut-off tail boost, the UHV switching device assembly uses optocoupier optical fiber to synchronously control the units of each lower withstand voltage power electronic device combination units in series, and distinguish the maximum total voltage borne by each unit after cut-off according to the same M interval voltage levels. In the process of tailing boost during cut-off, the real-time tailing boost borne by each unit is divided into M-level feedback output according to the voltage value, then send to M and gate entrances respectively with the same grade interval voltage. Each and gate output is then transmitted to the control input terminals of the upper interval voltage of each lower withstand voltage power electronic switching device combination unit by optocoupler optical fiber. When the trailing voltage of each lower withstand voltage power electronic switching device combination model units reaches the top of the same original interval voltage before entering the upper interval voltage together, to start N turn-off trailing voltages of lower withstand voltage power electronic switching device assembly module units increase synchronously and equably, which makes the tail voltage borne by all lower withstand voltage power electronic switching device combination units always keeps the highly consistent interval voltage of the same level in the boost process of turning off the tail. Then the trailing voltage borne by the whole assembly and the actual interval voltage borne by each unit simultaneously increase safely in sync with the voltage conversion of each interval in the tail stage. Until the trailing current disappears, the UHV switching device assembly achieves a perfect cutoff effect, which prevents the actual voltage lag borne by individual units of lower withstand voltage power electronic switching device combination in the series combination of power electronic switching devices from being lower than or beyond the voltage between them. Thus, an UHV switching device assembly with an excellent UHV total pressure resistance combined performance is formed, and with LC circuit in series or in parallel to form an UHV range of single or full bridge or half bridge high frequency power electronic transformer to solve the bottleneck of technology in this industry.

The embodiments of the invention relates to a circuit for improving the switching speed of a power electronic switching chip and its application are as follow:

### Embodiment 1

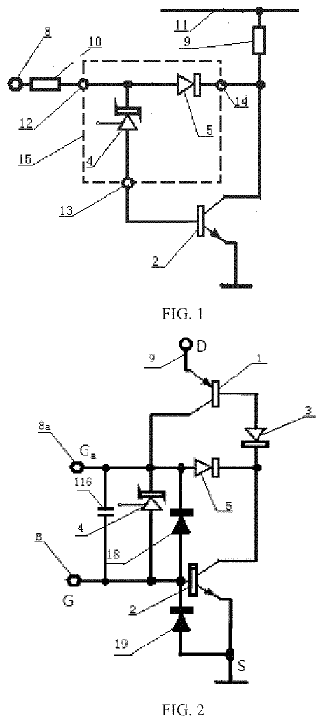

As shown in FIG. 1, the invention provides an auxiliary simulated saturation voltage independent module, the figure includes: power transistor 2, simulated saturation voltage setting voltage unit 4, collector simulated saturation voltage clamping diode 5, load resistor R_{f} 9, drive pulse current limiting resistor Rᵢ 10, power supply voltage 11, auxiliary simulated saturation voltage independent module driving pulse input terminal 12, auxiliary simulated saturation voltage independent module driving pulse output end 13, auxiliary simulated saturation voltage independent module clamping end 14, in the dashed box is the auxiliary simulated saturation voltage independent module 15. The circuit structure of the module is that the anode of the simulated saturation voltage setting voltage unit 4 is connected to the base of the NPN power transistor of the power electronic switching chip (the single-stage “Darlington” transistor) or the base of the NPN power transistor of the power electronic switching chip of the GTR module 2, the cathode is connected to the anode of the collector simulated saturation voltage clamping diode 5, and the cathode of the collector simulated saturation voltage clamping diode 5 is connected to the NPN power transistor of power electronic switch chip or the collector of the NPN power transistor of the power electronic switching chip of the GTR module 2, the conduction pulse is input via the pulse input terminal 8 through the current limiting resistance 10 to the anode connection of the auxiliary simulated saturation voltage independent module drive pulse input terminal 12 and collector simulated saturation voltage clamping diode 5, which makes the NPN power transistor of the power electronic switching chip conduct on the simulated saturation conduction voltage.

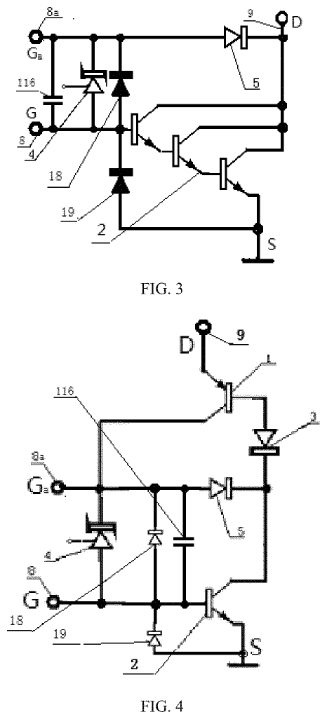

A circuit of the high speed power electronic switching devices or modules with high conduction acceleration and specific circuit structures as shown in FIG. 2, FIG. 3, and FIG. 4:

FIG. 2 is the schematic diagram of the circuit of the thyristor high-speed power electronic switching module with high simulated saturation conduction speed increase and low turn-off power consumption, super high current and super high voltage endurance, which comprises PNP power transistor 1, NPN power transistor 2, diode 3, quasi saturation voltage setting diode voltage unit 4. collector quasi saturation voltage clamping diodes 5, diode 18, diode 19, conduction control pulse input terminal 8. conduction control pulse input terminal 8a. thyristor high-speed power electronic switch module output end 9. special effect capacitance 116. The emitter of PNP power transistor 1 is used as the output end 9 of the anode D of the thyristor high-speed power electronic switching module, its base is connected with the anode of diode 3, and its collector is connected with the anode of the collector quasi saturation voltage clamping diodes 5. The cathodes of diode 3, collector quasi saturation voltage clamping diodes 5 are connected to the collector of NPN power transistor 2. The emitter of NPN power transistor 2 is connected to the anode of diode 19 and serves as the ground terminal S of the thyristor high-speed power electronic switching module. The base of NPN power transistor 2 is connected with the anode of diode 18 and the anode of the simulated saturation voltage setting voltage unit 4 and is used as the control input G terminal 8 of the thyristor high-speed power electronic switching module. The cathode of diode 18 and the cathode of simulated saturation voltage setting voltage unit 4 are connected and connected to the collector of PNP power transistor 1 as the control input Ga terminal 8a of the thyristor high-speed power electronic switching module. Both ends of the special effect capacitance 116 are in parallel with the two ends of diode 18. The conduction control pulse of the input conduction control pulse input terminal 8 makes the thyristor high-speed power electronic switching module in the traditional low saturation conduction state. According to the requirements of circuit application, the time-conduction control pulse is transferred to the conduction control pulse input terminal 8a. After that, the carrier density of the thyristor high-speed power electronic switching module is rapidly reduced and transferred to the continuous conduction state of high simulated saturation voltage and waiting for shutdown. The thyristor is quickly switched off as soon as the input terminal 8a pulse disappears. The length of this period depends on the requirement of specific circuit application. It depends on that the thyristor high-speed power electronic switch module can fully turn into the high simulated saturation conduction state to have the ideal acceleration function in the trailing stage.

FIG. 3 is the schematic diagram of the circuit of low turn-off power GTR high speed power electronic switching module with high simulated saturation conduction speed increase (or composed of the disaggregated element). It comprises Darlington GTR module 2, quasi saturation voltage setting diode voltage unit 4, collector quasi saturation voltage clamping diodes 5, diode 18, diode 19, conduction control pulse input terminal 8, conduction control pulse input terminal 8a, GTR high-speed power electronic switch module output end 9, special effect capacitance 116. The collector of Darlington GTR module 2 is connected with the cathode of the collector quasi saturation voltage clamping diodes 5 as the output end 9 of the anode D of GTR power electronic switching module, the anode of the collector quasi saturation voltage clamping diodes 5, the cathode of diode 18 and the cathode of quasi saturation voltage selling diode voltage unit 4 are connected to the control pulse input terminal 8a as the conduction control input Ga terminal of GTR high-speed power electronic switching module, conduction control pulse input terminal 8, the anode of diode 18, the anode of quasi saturation voltage setting diode voltage unit 4 and the cathode of diode 19 are connected to the base of Darlington GTR module 2 as the conduction control input Ga terminal of GTR high-speed power electronic switching module, the emitter of the Darlington GTR module 2 is connected to the anode of diode 19 as the S-ground terminal of the GTR high-speed power electronic switching module, the two ends of the special effect capacitance 116 are connected in parallel with the two ends of the diode 18. The conduction control pulse of the input conduction control pulse input terminal 8 makes the GTR high-speed power electronic switching module in the traditional low saturation conduction state. According to the requirements of circuit application, the time-conduction control pulse is transferred to the conduction control pulse input terminal 8a. After that, the carrier density of the GTR high-speed power electronic switching module is rapidly reduced and transferred to the continuous conduction state of high simulated saturation voltage and waiting for shutdown.

FIG. 4 is the schematic diagram of the circuit of low turn-off power IGBT high speed power electronic switching module with high simulated saturation conduction speed increase, which comprises PNP power transistor 1, NPN power transistor 2, diode 3, quasi saturation voltage setting diode voltage unit 4, collector quasi saturation voltage clamping diodes 5, diode 18, diode 19, conduction control pulse input terminal 8, conduction control pulse input terminal 8a, IGBT high-speed power electronic switch module output end 9, special effect capacitance 116. The emitter of PNP power transistor i is used as the output end of the anode D of the IGBT high speed power electronic switching module, its base is connected with the anode of diode 3, and its collector is connected with the anode of the collector quasi saturation voltage clamping diodes 5, the cathode of quasi saturation voltage setting diode voltage unit 4 and the cathode of diode 18 are connected as the control pulse input Ga terminal 8a. The cathode of diode 3 and the cathode of the collector quasi saturation voltage clamping diodes 5 are connected to the collector of NPN power transistor 2. The emitter of NPN power transistor 2 and the anode of diode 19 are connected and serves as the ground terminal S of the IGBT high speed power electronic switching module . The base of NPN power transistor 2, the anode of diode 18, the anode of quasi saturation voltage setting diode voltage unit 4 and the cathode of diode 19 are connected and serves as the control pulse input G terminal 8. Both ends of the special effect capacitance 116 are in parallel with the two ends of diode 18. The front stage field effect transistor is input into the conduction control pulse of the conduction control pulse input terminal 8, which makes the IGBT high speed power electronic switching module in the traditional low saturation conduction state. According to the time set by the requirements of circuit application, conduction control pulse is transferred to the conduction control pulse input terminal 8a. After that, IGBT high speed power electronic switching module is transferred to the continuous conduction state of high simulated saturation voltage and waiting for shutdown.

### Embodiment 2

FIG. 5 is the schematic diagram of power electronics transformer circuit with high frequency reactive power combined by a single high speed power electronics switch module and LC circuit, which comprises high speed power electronic switching devices or modules 20 with high simulated saturation conduction, reactive power capacitance 23 in the LC circuit, as the transformer and converter output primary winding 24 as the main inductance of the reactive power LC circuit, the tap 24c of the primary winding 24, the secondary winding 25 of the transformer and converter output, inductance 22, capacitor 122, current limiting resistor 27, capacitor 28, transformer converter 32, power positive terminal 30, the reactive power LC main circuit is formed in parallel by the capacitance 23 and the primary winding 24 of the transformer and converter output. One end of the LC main circuit is connected to the D pole of the high-speed power electronic switching module 20, the other end is connected to the end of capacitance 28, the other end of capacitance 28 is connected to the current limiting resistor 27. the other end of the current limiting resistor 27 is connected to the G pole of the high-speed power electronic switching module 20, one end of the inductance 22 is connected to one end of the capacitance 122 and is connected to the tap 24c of the primary winding 24 of the transformer and converter output, the other end of the inductance 22 is connected to the power positive terminal 30, the other end of capacitance 122 is grounded, the S pole of high speed power electronic switching module 20 is grounded.

### Embodiment 3

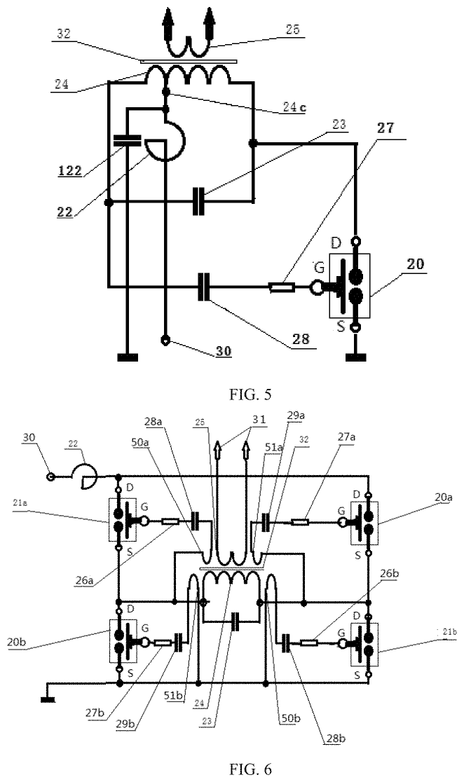

FIG. 6 is the schematic diagram of self-excited power electronics transformer circuit of parallel full bridge with high frequency reactive power, which comprises 20a, 20b, 21a, 21b four high-speed power electronic switching modules with simulated saturation and high conduction acceleration, reactive power hedge inductance 22, reactive power LC circuit capacitance 23, the transformer and converter output primary winding 24 as the main inductance of the reactive power LC circuit, the secondary winding 25 of the transformer and converter output, four bridge arm variable pressure and flux output control pulse current limiting resistance 26a, 26b, 27a, 27b, the capacitance 28a, 28b, 29a, 291), the power positive terminal 30, the transformer and converter output end 31, the transformer converter 32, the self excited feedback winding 50a, 50b, 51a, 51b. One end of the inductance 22 is connected to the power positive terminal 30, the other end is connected to the D pole of the high-speed power electronic switching module 20a, 21a, the S pole of the high-speed power electronic switching module 21a is connected to the D pole of the high-speed power electronic switching module 20b, the S pole of the high-speed power electronic switching module 20a is connected to the D pole of the high-speed power electronic switching module 21b, the S pole of the high-speed power electronic switching module 20b, 21b is grounded, the end of the self excited feedback winding 50a is connected to the S pole of the high-speed power electronic switching module 21a, the other end is connected to the capacitance 28a, the other end of the capacitance 28a is connected to the resistance 26a, the other end of the resistance 26a is connected to the G pole of the high-speed power electronic switching module 21a, the end of the self excited feedback winding 50b is connected to the S pole of the high-speed power electronic switching module 21b, the other end is connected to the capacitance 28b, the other end of the capacitance 28b is connected to the resistance 26b, the other end of the resistance 26b is connected to the G pole of the high-speed power electronic switching module 21b, the end of the self excited feedback winding 51a is connected to the S pole of the high-speed power electronic switching module 20a, the other end is connected to the capacitance 29a, the other end of the capacitance 29a is connected to the resistance 27a, the other end of the resistance 27a is connected to the G pole of the high-speed power electronic switching module 20a, the end of the self excited feedback winding 51b is connected to the S pole of the high-speed power electronic switching module 20b, the other end is connected to the capacitance 29b, the other end of the capacitance 29b is connected to the resistance 27b, the other end of the resistance 27b is connected to the G pole of the high-speed power electronic switching module 20b, the end of the capacitance 23 is connected to the end of the primary winding 24 of the transformer and converter output, and then connected to the S pole of the high-speed power electronic switching module 20a, the other end of the capacitance 23 is connected to the other end of the primary winding 24 of the transformer and converter output, and then connected to the S pole of the high-speed power electronic switching module 21a.

### Embodiment 4

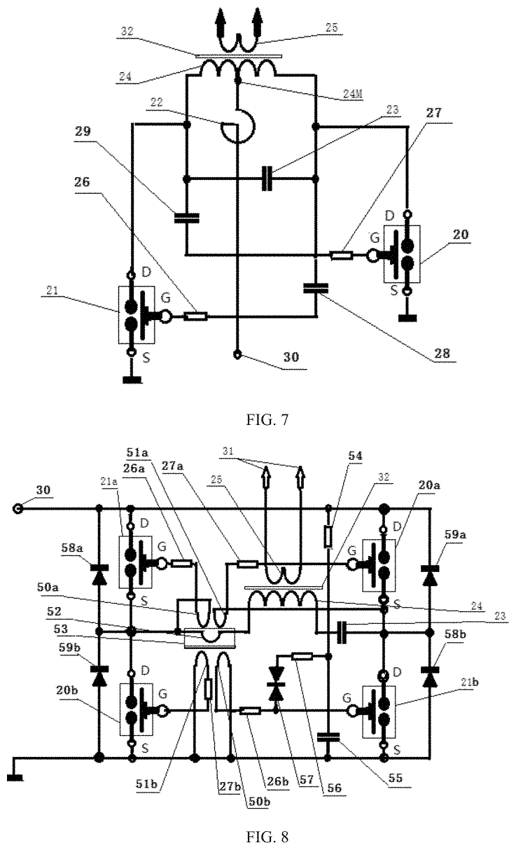

FIG. 7 is the schematic diagram of self-excited power electronics transformer circuit of parallel half bridge with high frequency reactive power, which comprises 20, 21 two high-speed power electronic switching modules with simulated saturation and high conduction acceleration, inductance 22, capacitance 23, the transformer and converter output primary winding 24 as the main inductance of the reactive power LC circuit, the centre tap 24M of the primary winding 24, the secondary winding 25 of the transformer and converter output, the current limiting resistance 26, 27, the capacitance 28, 29, the power positive terminal 30, the transformer converter 32. The end of the inductance 22 is connected to the power positive terminal 30, the other end is connected to the centre tap 24M of the primary winding 24 of the transformer and converter output, the D pole of the high-speed power electronic switching module 20 is connected to the end of the primary winding 24 of the transformer and converter output, the D pole of the high-speed power electronic switching module 21 is connected to the other end of the primary winding 24 of the transformer and converter output, both of the two S poles of the high-speed power electronic switching modules are grounded, the end of the capacitance 23 is connected to the D pole of the high-speed power electronic switching module 20, the other end is connected to the D pole of the high-speed power electronic switching module 21, the D pole of the high-speed power electronic switching module 20 is connected to the end of capacitance 28, the other end of capacitance 28 is connected to the end of resistance 26, the other end of resistance 26 is connected to the G pole of the high-speed power electronic switching module 21, the D pole of the high-speed power electronic switching module 21 is connected to the end of capacitance 29, the other end of capacitance 29 is connected to the end of resistance 27, the other end of resistance 27 is connected to the G pole of the high-speed power electronic switching module 20.

### Embodiment 5

FIG, 8 is the schematic diagram of self-excited power electronics transformer circuit of series full bridge with high frequency reactive power, which comprises 20a, 20b, 21a, 21b four high-speed power electronic switching modules with simulated saturation and high conduction acceleration, capacitance 23, the transformer and converter output primary winding 24 as the main inductance of the reactive power LC circuit, the secondary winding 25 of the transformer and converter output, the current limiting resistance 26a, 26b, 27a, 27b, the resistance 54, the capacitance 55, the resistance 56, the bidirectional diode 57, the power positive terminal 30, the transformer and converter output end 31, the transformer converter 32, the self excited feedback winding 50a, 50b, 51a, 51b, 52, the feedback winding combination 53, the overvoltage diode 58a, 58b, 59a, 59b. The power positive terminal 30 is connected to the D pole of the high-speed power electronic switching module 20a, 21a, the S pole of the high-speed power electronic switching module 20b, 21b is grounded, the S pole of the high-speed power electronic switching module 21a is connected to the D pole of the high-speed power electronic switching module 20b, the S pole of the high-speed power electronic switching module 20a is connected to the D pole of the high-speed power electronic switching module 21b, the end of the capacitance 23 is connected to the end of the primary winding 24 of the transformer and converter output, the other end of the capacitance 23 is connected to the S pole of the high-speed power electronic switching module 20a, the other end of the primary winding 24 of the transformer and converter output is connected to the end of self excited feedback winding 52, the other end of self excited feedback winding 52 is connected to the S pole of the high-speed power electronic switching module 21a, the end of self excited feedback winding 50a is connected to the S pole of the high-speed power electronic switching module 21a, the other end is connected to the resistance 26a, the other end of the resistance 26a is connected to the G pole of the high-speed power electronic switching module 21a, the end of self excited feedback winding 51a is connected to the S pole of the high-speed power electronic switching module 20a, the other end of the resistance 27a, the other end of the resistance 27a is connected to the G pole of the high-speed power electronic switching module 20a, the end of self excited feedback winding 51b is connected to the S pole of the high-speed power electronic switching module 20b, the other end is connected to the resistance 27b, the other end of the resistance 27b is connected to the G pole of the high-speed power electronic switching module 20b, the end of self excited feedback winding 50b is connected to the S pole of the high-speed power electronic switching module 21b, the other end is connected to the resistance 26b, the other end of the resistance 26b is connected to the G pole of the high-speed power electronic switching module 21b, the end of the resistance 54 is connected to the power positive terminal 30, the other end is connected to the capacitance 55 and the resistance 56, the other end of the resistance 56 is connected to the bidirectional diode 57, the other end of the capacitance 55 is grounded, the other end of the bidirectional diode 57 is connected to the G pole of the high-speed power electronic switching module 21b, the anode of the diode 58a is connected to the S pole of the high-speed power electronic switching module 21a, the cathode is connected to the D pole of the high-speed power electronic switching module 21a, the anode of the diode 59a is connected to the S pole of the high-speed power electronic switching module 20a, the cathode is connected to the D pole of the high-speed power electronic switching module 20a, the anode of the diode 58b is connected to the S pole of the high-speed power electronic switching module 21b, the cathode is connected to the D pole of the high-speed power electronic switching module 21h, the anode of the diode 59b is connected to the S pole of the high-speed power electronic switching module 20b, the cathode is connected to the D pole of the high-speed power electronic switching module 20b.

### Embodiment 6

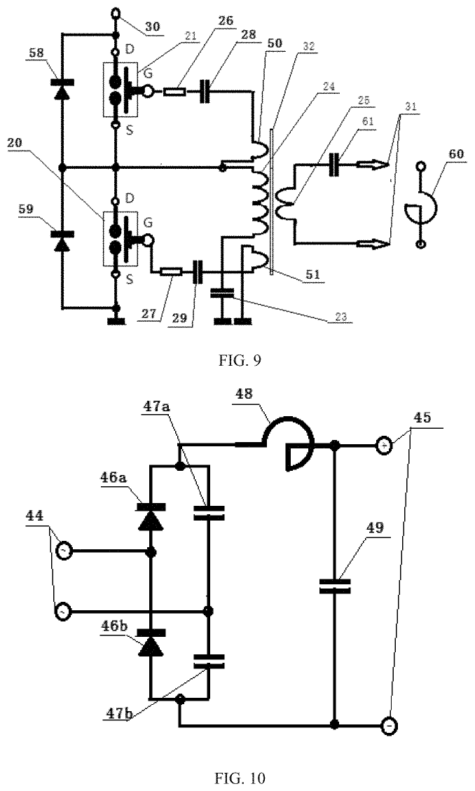

FIG. 9 is the schematic diagram of self-excited power electronics transformer circuit of series half bridge with high frequency reactive power, which comprises 20, 21 two high-speed power electronic switching modules with simulated saturation and high conduction acceleration, capacitance 23, the transformer and converter output primary winding 24 as the main inductance of the reactive power LC circuit, the secondary winding 25 of the transformer and converter output, the secondary winding output 31, the self excited feedback winding 50, 51, the diode 58, 59, the load winding 60, the increasing reactive power capacitance 61, the current limiting resistance 26, 27, the capacitance 28, 29, the power positive terminal 30, the transformer converter 32. The D pole of the high-speed power electronic switching module 21 is connected to the power positive terminal 30, the S pole of the high-speed power electronic switching module 21 is connected to the end of the primary winding 24 of the transformer and converter output and the D pole of the high-speed power electronic switching module 20, the other end of the primary winding 24 of the transformer and converter output is connected to the capacitance 23, the other end of the capacitance is grounded, the S pole of the high-speed power electronic switching module 20, the end of the secondary winding 25 is connected to the capacitance 61, the other end of the capacitance 61 and the other end of the secondary winding 25 are connected to the load winding 60 as the output end 31, the end of the self excited feedback winding 50 is connected to the S end of the high-speed power electronic switch module 21, the other end is connected to the capacitance 28, the other end of the capacitance 28 is connected to the end of the resistance 26, the other end of the resistance 26 is connected to the G pole of the high-speed power electronic switching module 21, the end of the self excited feedback winding 51 is connected to the S end of the high-speed power electronic switch module 20, the other end is connected to the end of the capacitance 29, the other end of the capacitance 29 is connected to the end of the resistance 27, the other end of the resistance 27 is connected to the G pole of the high-speed power electronic switching module 20, the anode of diode 58 is connected to the S pole of the high-speed power electronic switching module 21, the cathode is connected to the D pole of the high-speed power electronic switching module 21, the anode of diode 59 is connected to the S pole of the high-speed power electronic switching module 20, the cathode is connected to the D pole of the high-speed power electronic switching module 20. The load winding 60, which is used in electro-magnetization of water flow, is wound around the outside of the water flow pipe.

FIG. 10 is the circuit diagram of a half-bridge rectifier unit used for converting ac power supply to DC power distribution in a transmission line with DC up and down voltage of power electronics transformers with high frequency reactive power by push-pull complementary filter capacitance to meet 360° full conduction requirements to avoid power factor problems, which comprises AC input port 44. DC output port 45, half bridge rectifier diode 46a, 46b, push pull filter capacitance 47a, 47b, filter inductance 48, filter capacitance 49. The anode of half bridge rectifier diode 46a is connected to the cathode of half bridge rectifier diode 46b as a port of AC input 44. the cathode of the half bridge rectifier diode 46a is connected to one end of the filter inductance 48, the other end of the filter inductance 48 is connected to the positive terminal of the DC output port 45, the anode of half bridge rectifier diode 46b is connected to the negative terminal of the DC output port 45, the end of push pull filter capacitance 47a is connected to the cathode of half bridge rectifier diode 46a, the other end is connected with the end of push-pull filter capacitance 47b and connected to the other end of AC input port 44, the other end of push pull filter capacitance 47b is connected to the anode of half bridge rectifier diode 46b, the end of filter capacitance 49 is connected with the anode of the half bridge rectifier diode 46b, and the other end is connected to the positive terminal of the DC output port 45.

### Embodiment 7

The schematic diagram of the circuit of a high-frequency power electronic buck-boost transformer used for long-distance UHV DC transmission lines to exchange alternating current with direct current, and direct current with direct current for power distribution, the schematic diagram of the circuit of the single combined module in the unit of the combined module of the power electronic switching device in series adopted by the UHV switching device assembly, the schematic diagram of the circuit of the UHV switching device component assembly obtained from the series combination of the units of N power electronic switching device combination modules.

FIG. 17 is the schematic diagram of the circuit of an UHV power electronics transformer consisting of a single UHV switching device assembly, which comprises a single UHV power electronic switching device assembly 20, capacitance 23 of reactive power LC circuit, the transformer and converter output primary winding 24 as the main inductance of the reactive power LC circuit, the secondary winding 25 of the transformer and converter output, inductance 22, capacitance 122, transformer converter 32, power positive terminal 30. The capacitance 23 is connected with the primary winding 24 of the transformer and converter output to form the reactive power LC main circuit, the end of the LC main circuit is connected to D pole of the UHV power electronic switching device assembly 20, the other end of the LC main circuit is connected with the end of the inductance 22 and the end of the capacitance 122, the other end of the inductance 22 is connected to the UHV power positive terminal 30, the other end of capacitance 122 is grounded, the S pole of the UHV power electronic switching device assembly 20 is grounded, the G pole of the UHV power electronic switching device assembly serves as the control input of the oscillating excitation switch.

FIG, 18 is the schematic diagram of the circuit of a parallel half bridge UHV power electronic transformer, which comprises 20, 21 two UHV power electronic switching device assemblies, reactive power hedge inductance 22, capacitance 23, the transformer and converter output primary winding 24 as the main inductance, the center tap 24M of the primary winding 24, the secondary winding 25 of the transformer and converter output, power positive terminal 30, transformer converter 32, the end of the reactive power hedge inductance 22 is connected to the power positive terminal 30, the other end is connected to the center tap 24M of the primary winding 24, the D pole of the UHV power electronic switching device assembly 20 is connected to the end of the primary winding 24, the D pole of the UHV power electronic switching device assembly 21 is connected to the other end of the primary winding 24. The S ends of the two UHV power electronic switching device assemblies are grounded. The end of the capacitor 23 is connected to the D pole of the UHV power electronic switching device assembly 20, and the other end is connected to the D pole of the UHV power electronic switching device assembly 21. The G pole of the UHV power electronic switching device assembly 21 and the G pole of the UHV power electronic switching device assembly 20 serve as the control input of the oscillating excitation switch.

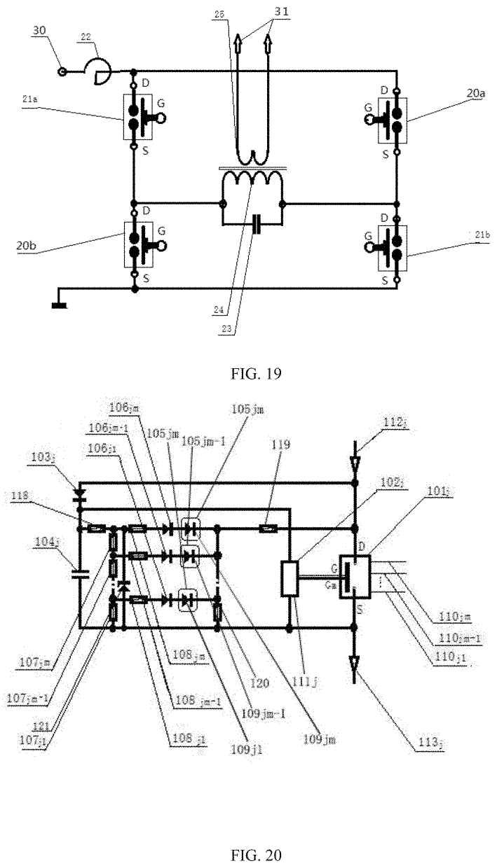

FIG. 19 is the schematic diagram of the circuit of a parallel full bridge UHV power electronic transformer, which comprises 20a, 20b, 21a, 21b four UHV power electronic switching device assemblies, reactive power hedge inductance 22, reactive power LC circuit capacitance 23, the transformer and converter output primary winding 24 as the main inductance of the reactive power LC circuit, the secondary winding 25 of the transformer and converter output, power positive terminal 30, transformer converter output 31, transformer converter 32, the end of the reactive power hedge inductance 22 is connected to the power positive terminal 30, the other end is connected to the D pole of the UHV power electronic switching device assembly 20a and 21a, the S pole of the UHV power electronic switching device assembly 21a is connected to the D pole of the UHV power electronic switching device assembly 20b. The S pole of the UHV power electronic switching device assembly 20a is connected to the D pole of the UHV power electronic switching device assembly 21h. The S pole of the UHV power electronic switching device assembly 20b and 21b is grounded. The G pole of the UHV power electronic switching device assembly 21a, the G pole of the UHV power electronic switching device assembly 20a, the G pole of the UHV power electronic switching device assembly 21b, and the G pole of the UHV power electronic switching device assembly 20b are used as the control input of the oscillation excitation switch. The end of the capacitance 23 is connected to the end of the inductance 24 and then connected to the S pole of the UHV power electronic switching device assembly 20a, the other end of the capacitance 23 is connected to the other end of the inductance 24, and then connected to the S-pole of the UHV power electronic switching device assembly 21a.

FIG, 20 is the schematic diagram of the circuit of the series unit j (j=1˜N) constituting each individual low withstand voltage power electronic switching device combination module in series in the component assembly of the UHV switching device, which comprises power electronic switching devices 101j, main switch drives pulser 102j, diode 103j. capacitor 104j, M optocoupler light emitting diodes 105jk (k=1˜M) M diodes 106jk, M partial voltage resistance 107jk, M current limiting resistors 108jk, M export optocoupler light emitting diodes 105jk optocoupler optical fiber 109jk of optocoupler light, M receiver optocoupler optical fiber 110jk, optocoupler optical fiber 111j synchronized with main switch drive pulser 102j, the series positive port 112j which is connected in series with other units and the series negative port 113j, buck sampling resistance 119j, 120j and current limiting resistance 118j. The D end of the power electronic switching device 101j is connected to the series positive port 112j, the S end of the power electronic switching device 101j is connected to the series negative port 113j, the G end and Ga end of the power electronic switching device 101j are connected to the control pulse output end of the main switch drive pulser 102j, the anode of diode 103j is connected to a series positive port 112j, the cathode is connected to the end of the capacitor of 104j, the other end of capacitor 104j is connected to the series negative port 113j, the power positive terminal of the main switch drive pulser 102j is connected to the cathode of the diode 103j, the power negative terminal of the main switch drive pulser 102j is connected to the series negative port 113j, M resistors 107jk in series, the upper end of the partial resistance 107jk is connected with the lower end of the partial resistance 107jk+4, and then the upper end of the resistance 107jM is connected to the cathode of the reference zener diode 121j and connected with the end of the current limiting resistance 118j, the other end of the current limiting resistor 118j is connected to the cathode of the diode 103j, the anode of the reference zener diode 121j is connected to the series negative port 113j, the lower end of the resistance 107j1 is connected to the series negative port 113j, the end of the buck sampling resistance 120J is connected to the series negative port 113j, the upper end of the buck sampling resistance 119j is connected to the series positive port 112j, the lower end is connected to the other end of the buck sampling resistance 120j and connected to the cathode of all the optocoupler light emitting diodes 105jk. The anode of each optocoupler light emitting diodes 105jk is connected to the cathode of 106jk, the anode of each diode 106jk is connected to the end of each resistor 108jk, the other end of each resistance 108jk is respectively connected to the connection point of the partial voltage resistance 107jk and 107jk+1.

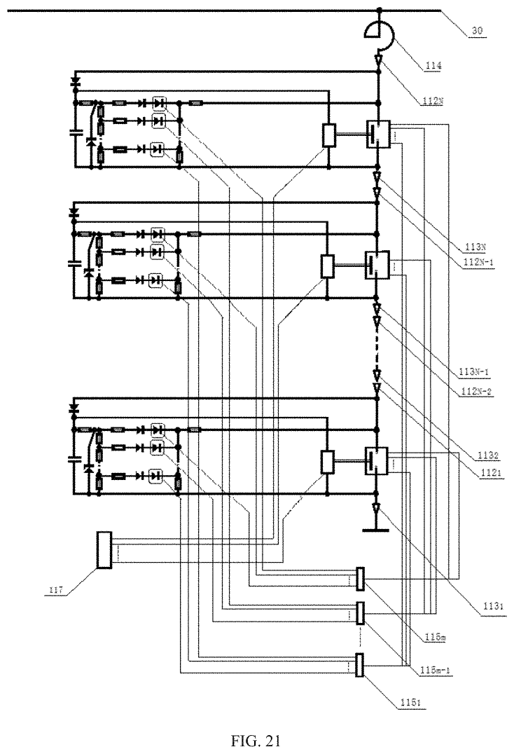

FIG. 21 is the schematic diagram of the total circuit of the component assembly of the switching device obtained from the series units j of N low withstand voltage power electronic switching device combination modules in series combination, which comprises identical series units j of N low withstand voltage power electronic switching device combination modules, UHV power positive terminal 30, load 114, and gate 115, N main switch pulsers 102j synchronous controller 117. Each individual series unit j of low withstand voltage power electronic switching device combination module is independently distinguished from other series units of low withstand voltage power electronic switching device combination modules, and the series positive port 112j which is connected in series with other units and the series negative port 113j are connected in series with other series units of low withstand voltage power electronic switching device combination modules. The series positive port 112j of each series unit of low withstand voltage power electronic switching device combination module is connected to the negative port 113j+1 of the last series unit of low withstand voltage power electronic switching device combination module. The serial positive port 112N of the highest series unit of low withstand voltage power electronic switching device combination module is connected to the end of load 114 as the D end of the component assembly of the UHV power electronic switch, the other end of load 114 is connected to UHV power positive terminal 30. The negative port 1131 of the lowest series unit of low withstand voltage power electronic switching device combination module is used as the S end of the component assembly of the UHV power electronic switch. There are M optocoupler light emitting diodes 105jk optocoupler optical fiber 109jk of optocoupler light derived from each k-level voltage interval. The N roots of each k-level voltage interval group are respectively connected to the N entrances of each M K-level and gate 115K. K-level and gate 115K output N outlets through the optocoupler optical fiber 110jk to send the k-level synchronous optocoupler light output by the voltage in the last interval to the k-level receiving end of the power electronic switching device combination unit 101j, and control the power electronic switching device combination unit 101j from the voltage state of the k-level interval to the voltage state of the next k+1 interval synchronously and uniformly.

The component assembly of UHV switching device serves as the power electronic switching device 20, 21 or 20a, 21a, 20b, 21b in the high frequency (UHV) power electronic transformer, which forms the high frequency power electronic buck-boost transformer for UHV conversion power distribution between exchange alternating current and direct current, direct current and direct current, direct current and alternating current.

### Embodiment 8

The transmission line uses a power supply that provides a strong high frequency heating current and uses the anti icing and ice melting facility composed of transmission lines erected by coaxial cable structure. As shown in FIG. 11, the power electronic transformer using a parallel half bridge to provide reactive power is used as the high frequency power supply for the simple anti icing and ice melting facility of the transmission line, which comprises 20, 21 two power electronic switching devices or modules with high simulated saturation voltage acceleration, inductance 22. capacitance 23, frequency reduction capacitance 62, frequency rise inductance 63, frequency down-conversion relay contact 64, frequency up-conversion relay contact 65, the transformer and converter output primary winding 24 as the main inductance, the center tap 24M of the primary winding 24, the output secondary winding 25, output port 31 and standby port 31a, current limiting resistors 26, 27, capacitance 28, 29, power positive terminal 30, high frequency reactive power power electronic transformer 32, reactive power compatilizing capacitance 61. The end of the inductance 22 is connected to the power positive terminal 30, the other end is connected to the center tap 24M of the primary winding 24, the D pole of the power electronic switching module 20 is connected to the end of the primary winding 24, the D pole of the power electronic switching module 21 is connected to the other end of the primary winding 24. The S ends of the power electronic switch are grounded. The end of the capacitance 23 is connected to the D pole of the power electronic switching module 20, and the other end is connected to the D pole of the power electronic switching module 21, the D pole of the power electronic switching module 20 is connected to the end of capacitance 28, the other end of the capacitance 28 is connected with the end of the resistance 26, the other end of the resistance 26 is connected with the G pole of the power electronic switching module 21; the D pole of the power electronic switch module 21 is connected to one end of the capacitance 29, the other end of the capacitance 29 is connected to the end of the resistance 27, and the other end of the resistance 27 is connected to the G pole of the power electronic switching module 20. Capacitance 61 is connected in parallel at both ends of secondary winding 25.

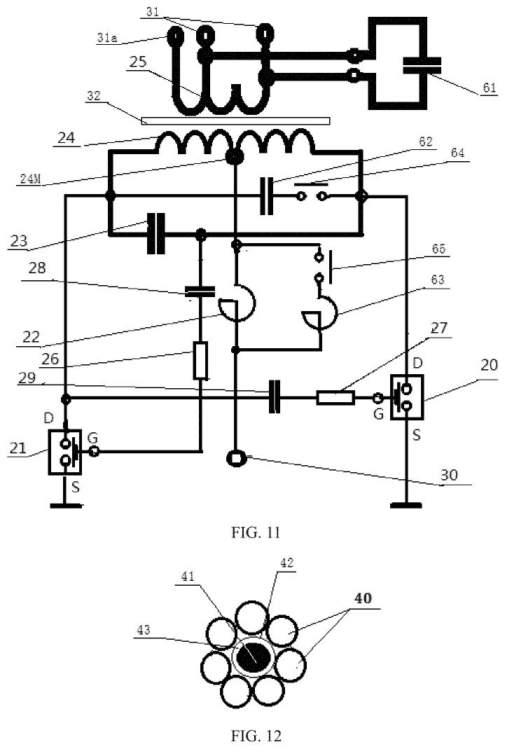

FIG. 12 is the section diagram of transmission line with coaxial cable structure, which comprises aluminum power line 40, force-bearing steel core line 41, aluminum foil 42, insulation layer 43. Insulation layer 43 provides electrical isolation between force-bearing steel core line 41, aluminum foil 42 and the aluminum power line 40 twisted outside aluminum foil 42.

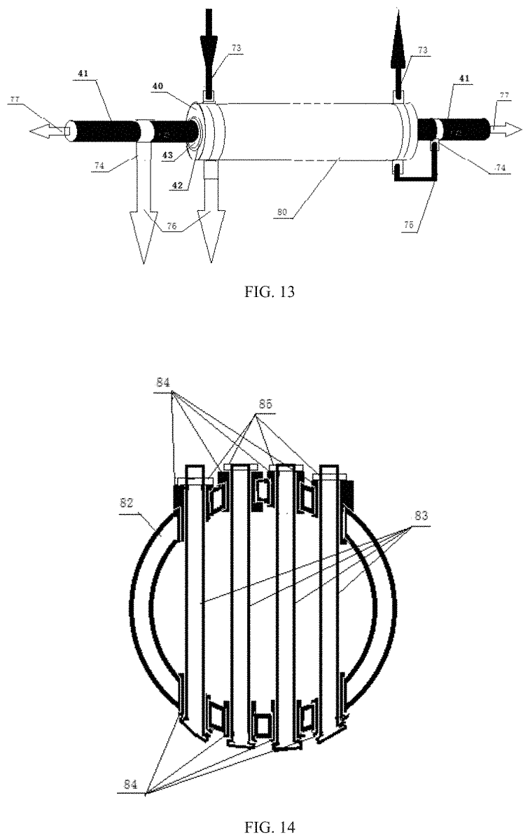

FIG. 13 is the schematic diagram of transmission line erection and connection with coaxial cable structure, which comprises force-bearing steel core line 41, aluminum foil 42, the aluminum power line 40 twisted outside aluminum foil 42, transmission line 80 of the power sending end and receiving end 73, force-bearing steel core line 41 passes into the leading end 74 of the heating high frequency current, short route 75, the bearing direction 77 of force-bearing steel core line 41, insulation layer between force-bearing steel core line 41 and aluminum foil 42, the force-bearing steel core line 41 and aluminum power line 40 at one end of transmission line 80 are connected to two ports 76 of the high frequency current of input heating transmission line 80, force-bearing steel core line 41 and aluminum power line 40 at the other end of transmission line 80 is connected by short route 75. When anti icing and ice melting are required, the end of transmission line 80 is connected to the high frequency current provided by the power electronic transformer power output port 31 or standby port 31a of the input heating transmission line through these two ports 76.

Electronic transformer power supply using high frequency power is treated with online anti icing and ice melting through online heating transmission lines, the corresponding transmission lines are simply improved from the traditional transmission lines which consist of the conventional high strength force steel core line twisted with conductive aluminum line on the outer layer: an insulating dielectric layer is arranged between the steel core line and the aluminum line, the aluminum line and the insulating dielectric layer are lined with a certain thickness of aluminum foil to shield the electromagnetic leakage of heating high-frequency current, forming such a transmission line with a coaxial cable structure as a heating load for the high frequency power electronic transformer power supply, the power factor is not so low in the simulation test. According to 100W per meter (the power consumption of a high power electric soldering iron) estimate, short-time heating power of per 10km line is about 1k kw, which is only the order of magnitude of low operating power of electric locomotive. It can be easily managed remotely to obtain perfect online anti icing and inciting effect.

### Embodiment 9

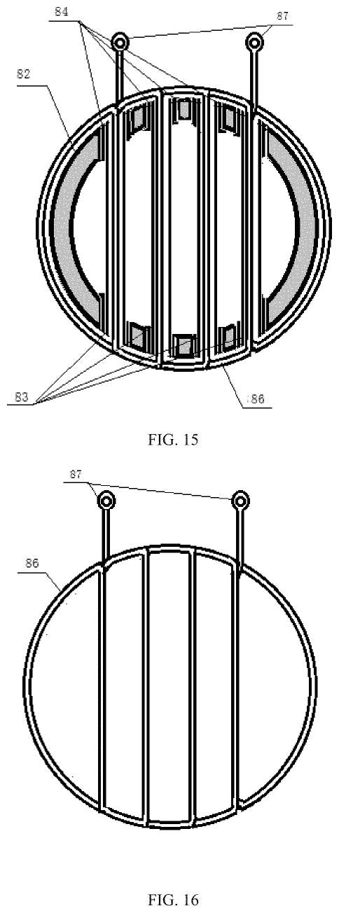

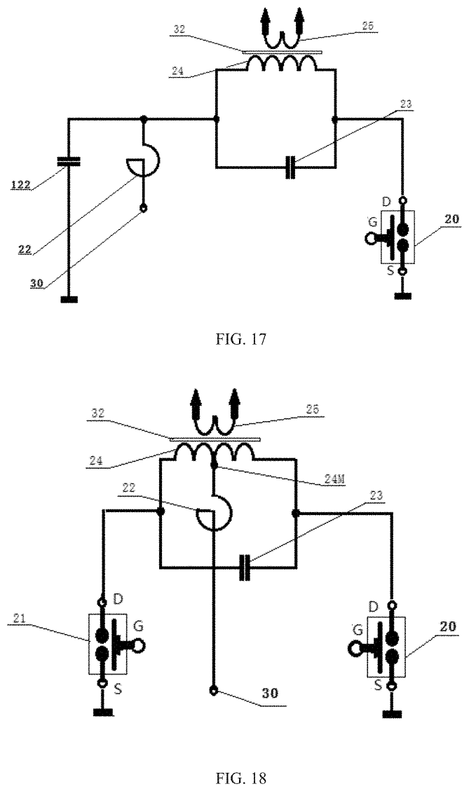

FIG. 8 shows the schematic diagram of the power supply circuit of the health care physiotherapy dredging device of the invention, which applies to the electromagnetic treatment of water supplied by the municipal water company. The specific embodiments are the coil winding setting schemes of FIG. 14, FIG. 15, FIG. 16 for the municipal water pipe with electromagnetization treatment of water. FIG. 14 comprises the water pipe 82, stainless steel pipe 83, water leakage preventing washer 84, leakage prevention compression nut 85, stainless steel pipe 83 through the water pipe 82, forming a complex connected area wire groove structure.

FIG. 15 comprises the water pipe 82, stainless steel pipe 83, water leakage preventing washer 84, the coil winding 86 arranged in the complex connected area wire groove, winding port 87.

FIG. 16 shows coil winding 86 and winding port 87 are listed separately outside the water pipe. Coil winding 86 acts as load winding 60 in FIG. 8.

The embodiment of the health care physiotherapy dredging device: all the water supplies used for cooking and drinking before entering the human body is passed through a coil of high frequency current to carry out the strong electro-magnetization treatment in advance, combined with ultrasound or music external massage method, and electromagnetic treatment of water both complement each other to the human body circulation, microcirculation system dredge, even can imitate the method of ultrasonic lithotriptic surgery, using a hand self-slap at the shock site after the extracorporeal ultrasonic surgery to effectively make the regenerated stone continue to slide down, or often combined with the patting of the heart and the head (or using headphones and other similar means to play music in corresponding parts) to unblock the network like blood vessels and help the prevention of myocardial infarction and cerebral infarction, and then use pure physical methods to unblock those circulation, microcirculation systems to get a “little rejuvenation” effect (especially this kind of stone microstone in the human body of all kinds of circulation, microcirculation system is likely to lead to some chronic diseases such as some kinds of senile disease like brain atrophy senile dementia. One of the most likely important factors in brain cell shrinkage is that the circulation network is blocked, preventing nutrients from entering the body, preventing waste toxins and other wastes from exiting the body. For example, patients with diabetes often take medicine for years and years, and drugs can not be discharged smoothly. The accumulation and blockage in the body cause serious necrosis complications and even life-threatening), and it also does not reduce the mineral content of drinking water. And it turns out that drinking electro-magnetized activated water over a period of two to three months and dredge by beating vibration are particularly helpful for the human body extracorporeal ultrasonic lithotripsy surgery: due to the failure to remove the gravel in time after the extracorporeal ultrasonic lithotripsy surgery:, and the failure to find and eliminate the causes of stones in the body, as a result, the crushed stones can still regenerate and solidify, resulting in partial “operation failure”. According to this operation, the postoperative stone discharge function of the extracorporeal ultrasonic lithotripsy surgery can be effectively transformed from “failure” to “successful discharge”. It can also remove all kinds of garbage such as drugs accumulated in the blood, presenting a good state of “if qi and blood are smooth, there will be no pain” to smooth the whole body and have a certain auxiliary medical care physiotherapy dredging function. This health care physiotherapy dredging device is installed in the city's public water source, such as the main water pipe of the water plant, it can be very convenient to treat the water source consumed by the whole city at very little cost to realize the health care of the whole people in the prevention and treatment of stones. Thus, the incidence and potential incidence of calculi in the general population will be greatly reduced, and the capacity of public health care in all countries around the world will be improved, Food and beverage production industry and some pharmaceutical enterprises can also refer to it. Because the water treated by electromagnetic field has the function of removing scale, it can also be used to prevent scale formation of water boiler and supply solar water heater for heating and prolong the service life of solar water heater which will reduce efficiency and failure due to scale formation. Because this process uses the pure physical method, and processing can be magnetic shielding and the human body can be far away from the effects of electromagnetic waves on the human body, and there is no electromagnetic pollution to the human body, and there is no adverse impact on water quality, so there will be no side effects on health. The health care physiotherapy dredging device only needs to use the electromagnetic coil around the water flow with the corresponding power supply. Its structure is simple and reliable. Although the process of treating water with electro-magnetization has become an existing technology in the industry, the corresponding technical characteristic of the health care physiotherapy dredging device of the invention for treating water with electro-magnetization to prevent and eliminate stones in human body is that high frequency power electronic transformer power supply uses high simulated saturation voltage accelerated power switching transistor to output stronger reactive power.

The certain specific embodiments of the invention are described in detail above in order to enable those skilled in the art to better understand the invention and thus to define more clearly the protection scope required by the invention. It should be noted that the above are only some specific embodiments conceived by the invention and only a part of the embodiments of the invention, wherein the specific and direct description of the relevant structures is only for the convenience of understanding and implementing the invention, and the specific features do not necessarily and directly limit the implementation scope of the invention. The conventional selection and replacement made by those skilled in the art under the guidance of the concept of the invention shall be deemed to be within the protection scope of the invention.

1. A circuit for improving the switching speed of a power electronic switching chip, which comprises a power electronic switching chip and a simulated saturation conduction high voltage function setting circuit, wherein the simulated saturation conduction high voltage function setting circuit is connected with the power electronic switching chip to form a high-speed power electronic switching module; the simulated saturation conduction high voltage function setting circuit greatly increases the voltage of the “saturation” conduction of the power electronic switching chip and correspondingly greatly reduces the carrier density in the base region of the power transistor of the power electronic switching chip, thereby improving the switching speed of power electronic switching chip;
the simulated saturation conduction high voltage function setting circuit includes NPN power transistor of power electronic switching chips, simulated saturation voltage setting voltage unit, clamping diode, load resistor R_{f}, drive pulse current limiting resistor Rᵢ, supply voltage, drive pulse input terminal, drive pulse output end, simulated saturation voltage clamp terminal;
the anode of the simulated saturation voltage setting voltage unit is connected to the base of the NPN type power transistor, which is the drive pulse output end, the cathode of the simulated saturation voltage setting voltage unit is connected with the anode of the clamping diode and the driving pulse input terminal, the cathode of the clamping diode is connected to the collector of NPN type power transistor via simulated saturation voltage clamping terminal, the conduction pulse is input to the drive pulse input terminal through the current limiting resistor via the pulse input terminal, and is connected to the base of the NPN type power transistor via the simulated saturation voltage setting voltage unit. In this way, the NPN power tube of the power electronic switching chip is conduced in the simulated saturation state of high conduction voltage.

2. A power electronics transformer circuit with a fast switching high frequency reactive power oscillating circuit, wherein the power electronics transformer circuit adopts the high-speed power electronic switching module according to claim 1, wherein the module and LC circuit are connected alone or as a bridge arm in series or in parallel to form a “single tube”, half bridge or full bridge LC self excitation or separate excitation oscillation circuit and to form a energy storage resonant circuit together with inductive or capacitive load elements, and with the filter capacitance push-pull complement to get 360° full period rectifier circuit.

3. An UHV power electronics transformer circuit composed of an UHV power electronic switching device assembly, characterized in that the component assembly of a high-speed power electronic switching module capable of withstanding UHV is matched alone or as a bridge arm with UHV LC circuit in series or in parallel with the single arm, half bridge or full bridge to form the LC oscillating circuit, and forms an UHV energy storage resonance circuit together with inductive or capacitive load elements, and with the filter capacitance push-pull complement 360° all conduction half bridge rectifier;
the component assembly of a high-speed power electronic switching module capable of withstanding UHV comprises identical multiple power electronic switching device combination units, UHV power supply positive end, load, and gate, multiple main switch pulsers, and synchronous controllers; the power electronic switching device combination unit is composed of the high-speed power electronic switching module in claim 1 as the basic unit.
